(19) United States
(12) Patent Application Publication
(10) Pub. No.: US 2003/0094134 A1
(43) Pub. Date: May 22, 2003

(54) Semiconductor manufacturing system with exhaust pipe, deposit elimination method for use with semiconductor manufacturing system, and method of manufacturing semiconductor device

(75) Inventor: Toshihiko Minami, Tokyo (JP)

Correspondence Address: McDermott, Will & Emery, 600 13th Street, N.W., Washington, DC, 20005-3096, US

(73) Assignee: Mitsubishi Denki Kabushiki Kaisha

(21) Appl. No.: 10/152,682

(22) Filed: May 23, 2002

(30) Foreign Application Priority Data
Nov. 22, 2001 (JP) 2001-357255

(51) Int. Cl. C23C 16/00

(52) U.S. Cl. 118/715; 427/248.1

(57) ABSTRACT

A reactive gas is supplied to a reaction chamber by way of a reactive gas supply pipe. The reactive gas is exhausted from the reaction chamber by way of a main exhaust pipe. Outside air is drawn into the reaction chamber by way of an air intake pipe by means of opening an air intake valve. Further, a main exhaust valve is closed, and a dust collection exhaust valve is opened. As a result, a by-product deposited on an interior wall of the reaction chamber and in the main exhaust pipe is exhausted by way of a dust collection exhaust pipe having exhaust power higher than that of the main exhaust pipe.

### BACKGROUND OF THE INVENTION

1. Field of the Invention

The present invention relates to a semiconductor manufacturing system, and more particularly, to a chemical vapor deposition system.

2. Description of the Background Art

FIG. 7 is a schematic cross-sectional view for describing a conventional semiconductor manufacturing system (chemical vapor deposition system).

As shown in FIG. 7, reference numeral 1 designates a reaction chamber; 2 designates a stage which is disposed in the reaction chamber 1 and holds a substrate A; 3 designates a reactive gas supply pipe connected to the reaction chamber 1; 4 designates a main exhaust pipe connected to the reaction chamber 1; and 5 designates a main exhaust valve provided on the main exhaust pipe 4.

Next will be described operation of the semiconductor manufacturing system; that is, a method of forming a thin film in the semiconductor manufacturing system.

First, the substrate A is transported into the reaction chamber 1. The substrate A is retained on the stage 2, which has been heated up to a predetermined temperature in advance.

A plurality of types of reactive gases are supplied into the reaction chamber 1 by way of the reactive gas supply pipe 3, thereafter plasma is induced as required. As a result, a thin film is formed on the surface of the substrate A through chemical vapor deposition.

After formation of the thin film, the reactive gas still remaining in the reaction chamber 1 (hereinafter called a “remaining gas”) is exhausted to the outside of the reaction chamber 1 by way of the main exhaust pipe 4. At this time, a portion of the remaining gas builds up on an interior wall of the reaction chamber 1 or the inside of the main exhaust pipe 4 as a by-product (particularly a powdery by-product).

After exhaust of the remaining gas, the substrate A having a thin film formed thereon is transported from the reaction chamber 1.

As mentioned above, when the remaining gas is exhausted from the reaction chamber 1 after formation of a thin film, a portion of the powdery by-product builds up on the interior wall surface of the reaction chamber 1 or in the main exhaust pipe 4. The amount of by-product built up increases with an increase in the number of wafers to be processed.

Thus, when the amount of by-product built up (hereinafter called a “deposit”) increases, the deposit interferes with and disturbs a current of air in the reaction chamber 1. Consequently, in-plane uniformity in the thickness of the thin film formed on the substrate A is deteriorated.

The deposit suspended in the reaction chamber 1 deposits on the substrate A as particles, thereby lowering a manufacturing yield.

The amount of by-product that builds up sharply increases in accordance with the number of wafers to be processed. For this reason, there has hitherto been a necessity for subjecting the reaction chamber 1 and the main exhaust pipe 4 to wet cleaning at frequent intervals. This in turn leads to a drop in the availability factor of the semiconductor manufacturing system.

### SUMMARY OF THE INVENTION

The present invention has been conceived to solve the previously-mentioned problems.

It is an object of the present invention is to enable easy elimination of by-products built up on an interior wall of a reaction chamber or in a main exhaust pipe.

Another object of the present invention is to improve the availability factor of a semiconductor manufacturing system by means of diminishing a frequency of wet cleaning.

A further object of the present invention is to form a high-quality thin film having superior in-plane uniformity and to involve a lower amount of particle deposit.

The above objects of the present invention are attained by a following semiconductor manufacturing system and by a following deposit elimination method for use with a semiconductor manufacturing system.

According to one aspect of the present invention, the semiconductor manufacturing system comprises a supply section for supplying a reactive gas to a reaction chamber. A first exhaust section exhausts the reactive gas from the reaction chamber. An air intake section draws outside air into the reaction chamber. A second exhaust section, which has exhaust power higher than that of the first exhaust section, exhausts a by-product deposited on an interior wall of the reaction chamber from the reaction chamber with the outside air.

According to another aspect of the present invention, in the deposit elimination method for use with a semiconductor manufacturing system, a reactive gas is first exhausted from a reaction chamber, after formation of a thin film on a substrate in the reaction chamber of the semiconductor manufacturing system. Outside air is drawn into the reaction chamber after exhaust of the reactive gas, and the outside air is exhausted from the reaction chamber at the same time. Wherein exhaust of the reactive gas is performed at a higher exhaust rate than exhaust of the outside air.

Other objects and further features of the present invention will be apparent from the following detailed description when read in conjunction with the accompanying drawings.

### BRIEF DESCRIPTION OF THE DRAWINGS

FIG. 1 is a schematic cross-sectional view for describing a semiconductor manufacturing system according to First Embodiment;

FIG. 2 is a schematic cross-sectional view for describing a semiconductor manufacturing system according to Second Embodiment;

FIG. 3 is a schematic cross-sectional view for describing a semiconductor manufacturing system according to Third Embodiment;

FIG. 4 is a schematic cross-sectional view for describing a semiconductor manufacturing system according to Fourth Embodiment;

FIG. 5 is a schematic cross-sectional view for describing a semiconductor manufacturing system according to Fifth Embodiment;

FIG. 6 is a schematic cross-sectional view for describing a semiconductor manufacturing system according to Sixth Embodiment; and

FIG. 7 is a schematic cross-sectional view for describing a conventional semiconductor manufacturing system.

### DETAILED DESCRIPTION OF THE PREFERRED EMBODIMENTS

In the following, principles and embodiments of the present invention will be described with reference to the accompanying drawings. The members and steps that are common to some of the drawings are given the same reference numerals and redundant descriptions therefore may be omitted.

First Embodiment

FIG. 1 is a schematic cross-sectional view for describing a semiconductor manufacturing system (i.e., a chemical vapor deposition system) according to First Embodiment.

As shown in FIG. 1, reference numeral 1 designates a reaction chamber; 2 designates a stage which is provided in the reaction chamber 1 and retains a substrate A; and 3 designates a reactive gas supply pipe which is connected to the reaction chamber 1 and supplies a reactive gas into the reaction chamber 1. Reference numeral 4 designates a main exhaust pipe which is connected to the reaction chamber 1 and serves as a first exhaust section for exhausting the reactive gas from the reaction chamber 1; 5 designates a main exhaust valve which is provided on the main exhaust pipe 4 and serves as a first exhaust valve; 6 designates a dust collection exhaust pipe which is provided so as to branch off from the main exhaust pipe 4 and serves as a second exhaust section having exhaust power higher than that of the main exhaust pipe 4; 7 designates a dust collection exhaust valve which is provided on the dust collection exhaust pipe 6 and serves as a second exhaust valve; 8 designates an air intake pipe (also called an “air inlet”) which is connected to the reaction chamber 1 and serves as an air intake section for drawing outside air into the reaction chamber 1 under suction; and 9 designates an air intake valve provided on the air intake pipe 8.

Here, the stage 2 is heated up to a predetermined temperature by means of, e.g., a heating mechanism (not shown) such as a heater.

The dust collection exhaust pipe 6 is for eliminating a by-product built on the interior wall of the reaction chamber 1 or in the main exhaust pipe 4 (particularly a powdery by-product) under suction, along with the outside air aspirated into the reaction chamber 1 by way of the air intake pipe 8.

The air intake pipe 8 and the reactive gas supply pipe 3 are separate from each other and are connected to the reaction chamber 1 at different positions.

In First Embodiment, the main exhaust pipe 4 is connected to a sidewall of the reaction chamber 1, and the air intake pipe 8 is connected to an upper surface of the reaction chamber 1. However, locations for connection are not limited to these locations. The main exhaust pipe 4 may be connected to an upper or lower surface of the reaction chamber 1, and the air intake pipe 8 may be connected to a sidewall or bottom surface of the reaction chamber 1. In any case, the air intake pipe 8 and the main exhaust pipe 4 are preferably formed in mutually-opposing positions (or positions separated from each other) on the reaction chamber 1. By virtue of such a connection layout, the current of air (which will be described later) is maintained in the reaction chamber 1 for a longer period of time as compared with the case where the air intake pipe 8 and the main exhaust pipe 4 are formed next to each other.

There will now be described a thin film forming method for use with the above-described semiconductor manufacturing system.

First, the substrate A is transported into the reaction chamber 1 and is retained on the stage 2, which has been heated up to a predetermined temperature beforehand.

For example, SiH₄ and O₂ are supplied as reactive gases into the reaction chamber 1 by way of the reactive gas supply pipe 3, thereafter plasma is induced as required. As a result, e.g. a silicon oxide film (as a thin film) is formed on the surface of the substrate A through chemical vapor deposition.

After formation of the silicon oxide film, the reactive gas still remaining in the reaction chamber 1 (hereinafter called a “remaining gas”) is exhausted to the outside of the reaction chamber 1 by way of the main exhaust pipe 4. At this time, a portion of the remaining gas builds up on an interior wall of the reaction chamber 1 or the inside of the main exhaust pipe 4 as a by-product (hereinafter called “deposit”). The amount of deposit increases with an increase in the number of times processing is performed.

After exhaust of the remaining gas, the substrate A having the thin film formed thereon is transported from the reaction chamber 1.

The next substrate and subsequent substrates are subjected to the foregoing processes, whereby a thin film is formed on each of the substrates.

The deposit elimination method for use with the semiconductor manufacturing system will now be described.

As mentioned above, when the number of times processing for forming a thin film is performed increases (i.e., the number of substrates to be processed increases), the amount of by-product built up on the interior wall of the reaction chamber 1 and in the main exhaust pipe 4 increases. Before the by-product builds up to a certain amount, the substrate having a thin film formed thereon is transported. Subsequently, supply of the reactive gas to the reaction chamber 1 from the reactive gas supply pipe 3 is ceased. The main exhaust valve 5 is closed, and the dust collection exhaust valve 7 and the air intake valve 9 are opened.

Here, “a certain amount” means the amount of deposit which induces air turbulence in the reaction chamber 1 to thereby adversely affect formation of a thin film (e.g., a drop in in-plane uniformity of thickness) or the amount of deposit at which a portion of deposit is suspended and which exceeds a permissible particle standard for a substrate. In First Embodiment, a determination as to whether or not a certain amount has been satisfied is made with reference to the number of substrates to be processed in the reaction chamber 1 or an RF-ON time.

By means of the opening and closing actions of the valves, the by-product (deposit) built up on the interior wall of the reaction chamber 1 and in the main exhaust pipe 4 is eliminated under suction. More specifically, a current of air develops as a result of the outside air that has been drawn into the reaction chamber 1 by way of the air intake pipe 8 being exhausted by way of the dust collection exhaust pipe 6. By means of the air current, the deposit is eliminated.

Closing action of the main exhaust valve 5, the opening action of the dust collection exhaust valve 7, and the opening action of the air intake valve 9 may be performed in any sequence. However, a closed state of the main exhaust valve 5, an opened state of the dust collection exhaust valve 6, and an opened state of the air intake valve 9 must be achieved simultaneously, thereby enhancing an effect of eliminating the deposit from the dust collection exhaust pipe 6 under suction. More specifically, the deposit can be eliminated efficiently.

After elimination of the deposit under suction has been completed, the air intake valve 9 is closed, and the dust collection exhaust valve 7 is also closed. Further, the main exhaust valve 5 is opened, thereby bringing the reaction chamber 1 into a state in which a thin film can be formed.

As has been described, in relation to the semiconductor manufacturing system and deposit elimination method according to the present invention, the dust collection exhaust pipe 6 having exhaust power higher than that of the main exhaust pipe 4 is provided so as to branch off from the main exhaust pipe 4. Aside from the reactive gas supply pipe 3, there is provided the air intake pipe 8 for drawing outside air into the reaction chamber 1 under suction. Before the by-product deposited on the interior wall of the reaction chamber 1 or the inside of the main exhaust pipe 4 affects a film deposition process, the outside air that has been drawn into the reaction chamber 1 by way of the air intake pipe 8 under suction is exhausted by way of the dust collection exhaust pipe 6, thereby inducing a current of air. By means of the air current, the deposit is eliminated under suction.

Accordingly, the deposit can be eliminated readily, thereby preventing occurrence of a disturbance in the air current in the reaction chamber 1. Thus, there can be inhibited suspension of particles from the deposit and deposition of particles on the substrate A. Therefore, there can be formed a high-quality thin film which has superior in-plane uniformity in thickness and involves deposition of few particles. The amount of by-product which builds up is maintained at a negligible level through repeated elimination of the deposit under suction. Hence, the cycle of wet cleaning of the reaction chamber 1 can be made longer, thereby improving the availability factor of the semiconductor manufacturing system.

In First Embodiment, the dust collection exhaust pipe 6 is provided so as to branch off from the main exhaust pipe 4. However, the location where the dust collection exhaust pipe 6 is to be connected is not limited to this. The dust collection exhaust pipe 6 may be provided directly on the reaction chamber 1 (the same also applies to Second through Sixth Embodiments to be described later).

In First Embodiment, the outside air is drawn by way of the air intake pipe 8 under suction. However, depending on the type of a thin film to be produced, an inert gas, such as N₂ gas (nitrogen gas) or Ar gas (argon gas), may be drawn by way of the air intake pipe 8 (the same also applies to Second through Sixth Embodiments to be described later). As a result, the amount of particles deposited on the substrate A can be reduced further.

Second Embodiment

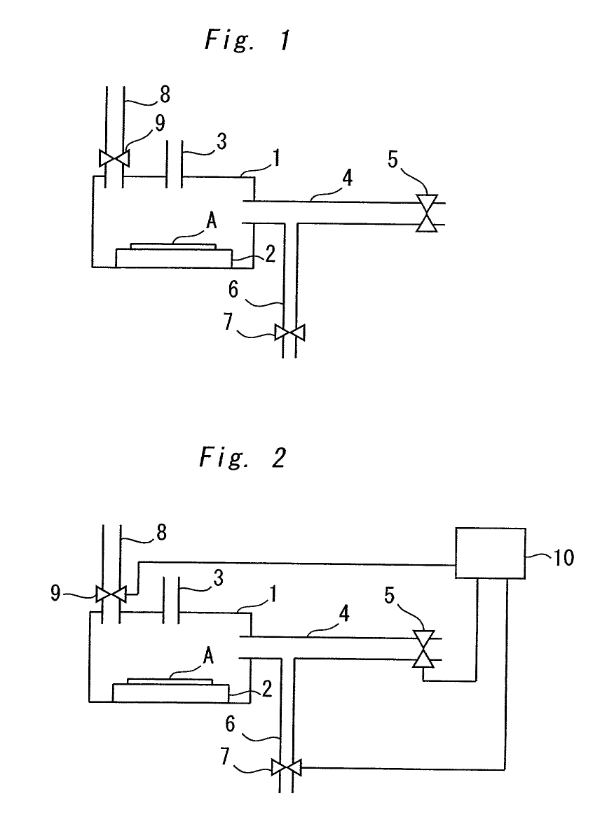

FIG. 2 is a schematic cross-sectional view for describing a semiconductor manufacturing system according to Second Embodiment.

The semiconductor manufacturing device according to Second Embodiment is characterized in that the semiconductor manufacturing system according to First Embodiment is provided with a control section 10 for controlling the opening/closing actions of the main exhaust valve 5, those of the dust collection exhaust valve 7, and those of the air intake valve 9.

Here, the control section 10 is connected to the main exhaust valve 5, the dust collection exhaust valve 7, and the air intake valve 9. The control section 10 automatically controls the opening/closing actions of the respective valves 5, 7, and 9 at desired timings; that is, timings at which a high effect of eliminating a deposit under suction is achieved.

The thin film forming method to be used in the semiconductor manufacturing system is identical with that described in connection with First Embodiment, and hence its explanation is omitted.

A deposit elimination method for use with the semiconductor manufacturing system will now be described.

As in the case of First Embodiment, before a by-product builds up to a certain amount on the interior wall of the reaction chamber 1 and in the main exhaust pipe 4 after formation of a thin film, the control section 10 ceases supply of a reactive gas into the reaction chamber 1 by way of the reactive gas supply pipe 3. The control section 10 further closes the main exhaust valve 5 and opens the dust collection valve 7 and the air intake valve 9. By means of valve opening/closing actions of the control section 10, the outside air drawn into the reaction chamber 1 by way of the air intake pipe 8 is exhausted to the outside by way of the dust collection exhaust pipe 6, thus inducing a current of air. By means of the current of air, the deposit is eliminated under suction.

After completion of elimination of the deposit under suction, the control section 10 closes the air intake valve 9 and the dust collection valve 7 and opens the main exhaust valve 5, thereby restoring the reaction chamber 1 to a state in which a thin film can be formed.

Accordingly, Second Embodiment yields the same advantage as that yielded in First Embodiment.

Further, the control section 10 can open and close the valves at desired timings. Hence, the deposit can be automatically eliminated under suction when necessary by means of a predetermined program. Accordingly, the deposit can be exhausted at the time of the maximum elimination effect. Further, cleaning of the interior wall of the reaction chamber 1 and that of the inside of the main exhaust pipe 4, which hitherto performed have been manually, can be automated.

Third Embodiment

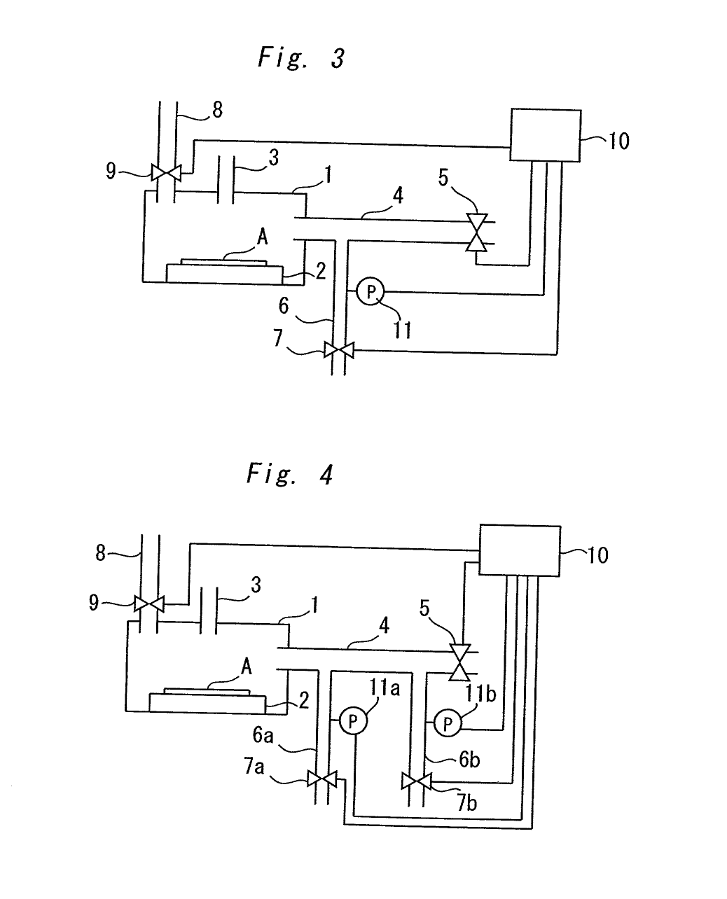

FIG. 3 is a schematic cross-sectional view for describing a semiconductor manufacturing system according to Third Embodiment.

The semiconductor manufacturing system according to Third Embodiment is characterized in that the semiconductor manufacturing system described in connection with Second Embodiment is provided with a pressure sensor 11 for sensing an internal pressure of the dust collection exhaust pipe 6.

Here, the pressure sensor 11 is disposed at a position on the dust collection exhaust pipe 6 close to the reaction chamber 1 rather than at a position close to the dust collection exhaust valve 7. The pressure sensor 11 is for sensing the internal pressure of the dust collection exhaust pipe 6, that is, for sensing the exhaust power of the dust collection exhaust pipe 6. The pressure sensor 11 is connected to the control section 10, thereby outputting a result of detection to the control section 10.

Also, the thin film forming method in the semiconductor manufacturing system is the same as that described in connection with First Embodiment. For this reason, explanation of the method is omitted in Third Embodiment.

A deposit elimination method for use with the semiconductor manufacturing system will now be described.

The method of eliminating deposits under suction is the same as that described in connection with Second Embodiment.

In Third Embodiment, the pressure sensor 11 detects the internal pressure of the dust collection exhaust pipe 6 during the course of an operation to be performed for eliminating a deposit under suction after formation of a thin film. A sensing result (pressure value) is output to the control section 10. As a result, when an internal pressure level of the dust collection exhaust pipe 6 has increased beyond a predetermined pressure level during the course of the operation for eliminating a deposit under suction; more specifically, when a considerable drop has arisen in the suction power (i.e., exhaust capacity) of the dust collection exhaust pipe 6, the control section 10 into which a sensing result (i.e., an abnormal pressure level) has been output from the pressure sensor 11 issues an alarm. Thus, an operator (worker) can ascertain an anomalous internal pressure of the dust collection exhaust pipe 6. Accordingly, in addition to the advantage yielded in Second Embodiment, there is also yielded an advantage of an improvement in the reliability of the semiconductor manufacturing system.

In Third Embodiment, the control section 10 monitors a sensing result output from the pressure sensor 11 at all times. However, the pressure sensor 11 maybe arranged so as to merely output an anomalous signal to the control section 10 when an anomalous pressure is detected.

The pressure sensor 11 may be disposed downstream from the dust collection exhaust valve 7, to thereby detect the pressure of the dust collection exhaust pipe 6.

Fourth Embodiment

FIG. 4 is a schematic cross-sectional view for describing a semiconductor manufacturing system according to Fourth Embodiment.

In the semiconductor manufacturing system according to Fourth Embodiment, a plurality of dust collection exhaust pipes 6a, 6b having exhaust power higher than that of the main exhaust pipe 4 are provided so as to branch off from the main exhaust pipe 4. A dust collection exhaust valve 7a and a pressure sensor 11a are provided in the dust collection exhaust pipe 6a, and a dust collection exhaust valve 7b and a pressure sensor 11b are provided in the dust collection exhaust pipe 6b.

The thin film forming method in the semiconductor manufacturing system is the same as that described in connection with First Embodiment. For this reason, explanation of the method is omitted in Fourth Embodiment.

A deposit elimination method for use with the semiconductor manufacturing system will now be described.

As in the case of First Embodiment, before a by-product builds up on the interior wall of the reaction chamber 1 and in the main exhaust pipe 4 to a certain amount (i.e., an amount which involves occurrence of a turbulent air current that adversely affects formation of a thin film), the control section 10 ceases supply of a reactive gas to the reaction chamber 1 by way of the reactive gas supply pipe 3, closes the main exhaust valve 5, and opens the dust collection exhaust valve 7a and the air intake valve 9. As a result, the deposit is eliminated from the dust collection exhaust pipe 6a under suction. At this time, the dust collection exhaust valve 7b remains closed. More specifically, only the dust collection exhaust pipe 6a is used for eliminating the deposit under suction, and the dust collection exhaust pipe 6b is not used.

When the pressure of the dust collection exhaust pipe 6a has increased beyond a preset pressure level during the course of the operation for eliminating the deposit under suction; namely, when a drop has arisen in the exhaust power (or suction power), the control section 10 determines that a drop has arisen in the exhaust power of the dust collection exhaust pipe 6a, from a signal output from the pressure sensor 11a provided in the dust collection exhaust pipe 6a. Simultaneous with this determination, the control section 10 closes the dust collection exhaust valve 7a and opens the dust collection exhaust valve 7b. As a result, the operation for eliminating a deposit under suction can be performed without interruption.

According to Fourth Embodiment, even when an anomalous pressure has arisen in any one of a plurality of dust collection exhaust pipes during the course of elimination of a deposit under suction, switching to another dust collection exhaust pipe can be effected, thereby enabling an uninterrupted, continuous elimination and suction operation. During operation of the other dust collection exhaust pipe, the dust collection exhaust pipe in which an anomalous pressure has arisen can be restored to a normal state. Accordingly, in addition to the advantage yielded in Third Embodiment, the availability factor of the semiconductor manufacturing system can be improved to a much greater extent.

Fourth Embodiment has described a case where the two dust collection exhaust pipes 6a, 6b are used. However, the present invention is not limited to such a case, and three or more dust collection exhaust pipes may be used. Even in such a case, there is yielded the same advantage as that yielded in a case where the two dust collection exhaust pipes 6a, 6b are used.

The dust collection exhaust pipes 6a, 6b may differ in exhaust power from each other, so long as they each have higher exhaust power than that of the main exhaust pipe 4.

In Fourth Embodiment, the control section 10 monitors a signal output from the pressure sensor 11 at all times. However, the pressure sensor 11a may be configured so as to merely output an anomalous signal when an anomalous pressure has arisen. In this case, upon receipt of a pressure anomalous signal from the pressure sensor 11a, the control section 10 closes the dust collection exhaust valve 7a and opens the dust collection exhaust valve 7b.

Fifth Embodiment

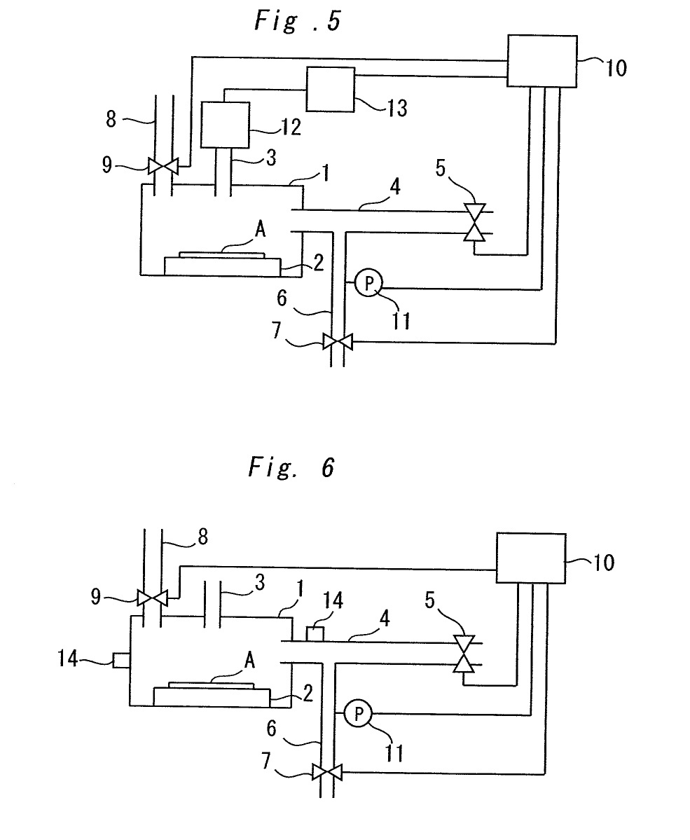

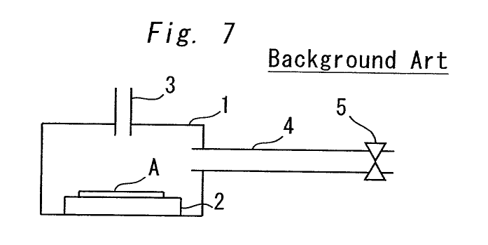

FIG. 5 is a schematic cross-sectional view for describing a semiconductor manufacturing system according to Fifth Embodiment.

The semiconductor manufacturing system according to Fifth Embodiment is characterized in that the semiconductor manufacturing system according to Third Embodiment is provided with a reactive gas supply device 12 for supplying a reactive gas to the reactive gas supply pipe 3, and a feedstock consumption level detection section (i.e., a supply volume detection section) 13 for detecting the amount of feedstock consumed by the reactive gas supply device 12 (i.e., a supply volume of reactive gas).

The reactive gas supply device 12 is a fluid feedstock tank for preserving a fluid from which a reactive gas originates, and in the present embodiment may be referred to as a fluid feedstock tank 12.

The feedstock consumption level detection section 13 detects a fluctuation in a fluid level of the fluid feedstock tank 12 and outputs a result of detection to the control section 10.

The thin film forming method for use in the semiconductor manufacturing system is the same as that described in connection with First Embodiment. For this reason, explanation of the method is omitted in Fourth Embodiment.

A deposit elimination method for use with the semiconductor manufacturing system will now be described.

As mentioned above, the thin film forming method is identical with that described in connection with First Embodiment. In Fifth Embodiment, the feedstock consumption level detection section 13 detects, at all times or periodically, the amount of feedstock (i.e., a reactive gas or a fluid) used at the time of formation of a thin film and outputs a result of detection to the control section 10. For instance, when the feedstock consumption level detection section 13 has detected a given fluctuation in the fluid level of the fluid feedstock tank 12, the control section 10 ceases supply of the reactive gas to the reaction chamber 1 from the reactive gas supply pipe 3 after transport of a substrate, on the basis of the detection result output from the feedstock consumption level detection section 13, closes the main exhaust valve 5, and opens the dust collection exhaust valve 7 and the air intake valve 9. As a result, the deposit deposited on the interior wall of the reaction chamber 1 and in the main exhaust pipe 4 is eliminated from the dust collection exhaust pipe 6 under suction.

Next, after completion of elimination and suction of the deposit, the control section 10 closes the air intake valve 9 and the dust collection exhaust valve 7 and opens the main exhaust valve 5, whereby the reaction chamber 1 returns to a state in which a thin film can be formed.

According to Fifth Embodiment, every time a certain amount of feedstock has been consumed, a deposit is eliminated under suction. Therefore, without fail, the deposit can be eliminated before the deposit affects a process for deposition of a film. Accordingly, elimination of a deposit under suction is repeated periodically. Hence, in addition to the advantage yielded in First Embodiment, there is also yielded an advantage of the amount of by-product to be deposited being maintained at a minute level at all times.

In Fifth Embodiment, the reactive gas supply section 12 is taken as a fluid feedstock tank. However, the reactive gas supply section 12 may be embodied as a gas cylinder filled with a reactive gas or as a gas supply line which serves as an ancillary facility.

Further, the feedstock consumption level detection section 13 detects a fluid level of liquid feedstock. However, the present invention is not limited to detecting the feedstock consumption level in this manner. The amount of feedstock consumed may be detected by means of an integrated flow rate of reactive gas, variations in the pressure of reactive gas, an integrated flow rate of fluid, or variations in the weight of fluid. Even this case yields the same advantage as that mentioned previously.

Sixth Embodiment

FIG. 6 is a schematic cross-sectional view for describing a semiconductor manufacturing system according to Sixth Embodiment.

The semiconductor manufacturing system according to Sixth Embodiment of the present invention is characterized in that the semiconductor manufacturing system described in connection with Third Embodiment is provided with a reactive by-product deposition volume detection section (hereinafter called a “deposition volume detection section”) 14 for detecting the amount of by-product deposited on the interior wall of the reaction chamber 1 and in the main exhaust pipe 4.

Here, the deposition volume detection section 14 is provided on the side wall of the reaction chamber 1 and in the main exhaust pipe 4. The deposition volume detection section 14 is connected to the control section 10. The deposition volume detection section 14 is configured so as to detect the amount of by-product deposited on the basis of transmittance or reflectance of light, by means of radiating light onto a portion of the main exhaust pipe 4 consisting of a transparent member or a window of transparent material provided on the side wall of the reaction chamber 1. The deposition volume detection section 14 detects the amount of by-product deposited on the interior wall of the reaction chamber 1 and in the main exhaust pipe 4 and outputs a result of detection to the control section 10.

The thin film forming method for use in the semiconductor manufacturing system is the same as that described in connection with First Embodiment. For this reason, explanation of the method is omitted in Fourth Embodiment.

A deposit elimination method for use with the semiconductor manufacturing system will now be described.

As mentioned above, the thin film forming method is identical with that described in connection with First Embodiment. The deposition volume detection section 14 detects, at all times or periodically, the amount of by-product deposited on the interior wall of the reaction chamber 1 and in the main exhaust pipe 4 and outputs a result of detection to the control section 10. For instance, when the deposition volume detection section 14 has detected a certain amount of deposit, the control section 10 ceases supply of a reactive gas to the reaction chamber 1 by way of the reactive gas supply pipe 3, closes the main exhaust valve 5, and opens the dust collection exhaust valve 7 and the air intake valve 9. As a result, the deposit deposited on the interior wall of the reaction chamber 1 and in the main exhaust pipe 4 is eliminated from the dust collection exhaust pipe 6 under suction.

After completion of elimination of a deposit under suction, the control section 10 closes the air intake valve 9 and the dust collection exhaust valve 7, and opens the main exhaust vale 5. As a result, the reaction chamber 1 returns to a state in which a thin film can be formed.

According to Sixth Embodiment, when the deposition volume detection section 14 has detected that a reactive by-product has been deposited to a certain amount, the deposit is eliminated under suction. Hence, the deposit can be eliminated without fail before affecting a film deposition process. Accordingly, elimination and suction of a deposit is iterated periodically, and hence there is yielded an advantage of the ability to maintain the volume of by-product deposited at a minute level at all times.

In Sixth Embodiment, a light radiation method is employed for detecting the volume of deposit by the deposition volume detection section 14. However, any method which enables detection of the volume of deposit may be employed.

In Sixth Embodiment, the deposition volume detection section 14 is provided outside the reaction chamber 1 or the main exhaust pipe 4. However, the deposition volume detection section 14 may be provided in the reaction chamber 1 or the main exhaust pipe 4.

This invention, when practiced illustratively in the manner described above, provides the following major effects:

According to the present invention, a by-product deposited on an interior wall of a reaction chamber or in a main exhaust pipe can be eliminated readily. Hence, the frequency of wet cleaning to be performed can be diminished, thereby enhancing the availability factor of the semiconductor manufacturing system. Further, there can be formed a high-quality thin film which has superior in-plane uniformity and involves a lower amount of particle deposit.

Further, the present invention is not limited to these embodiments, but variations and modifications may be made without departing from the scope of the present invention.

The entire disclosure of Japanese Patent Application No. 2001-357255 filed on Nov. 22, 2001 containing specification, claims, drawings and summary are incorporated herein by reference in its entirety.

What is claimed is:

1. A semiconductor manufacturing system for forming a thin film on a substrate, comprising:
a supply section for supplying a reactive gas to a reaction chamber;
a first exhaust section for exhausting the reactive gas from the reaction chamber;
an air intake section for drawing outside air into the reaction chamber; and
a second exhaust section which has exhaust power higher than that of said first exhaust section, said second exhaust section exhausting a by-product deposited on an interior wall of the reaction chamber from the reaction chamber together with the outside air.

2. The semiconductor manufacturing system according to claim 1, further comprising:
a first exhaust valve provided in said first exhaust section;
a second exhaust valve provided in said second exhaust section;
an air intake valve provided in said air intake section; and
a control section for controlling opening/closing actions of said first exhaust valve, said second exhaust valve and said air intake valve.

3. The semiconductor manufacturing system according to claim 2, further comprising:
a supply volume detection section connected to said supply section and for detecting a supply volume of the reactive gas,
wherein said control section controls the opening/closing actions of said first exhaust valve, those of said second exhaust valve and those of said air intake valve on the basis of a result detected by said supply volume detection section.

4. The semiconductor manufacturing system according to claim 2, further comprising:
a deposit volume detection section for detecting a volume of the by-product deposited on the interior wall surface of the reaction chamber,
wherein said control section controls the opening/closing actions of said first exhaust valve, those of said second exhaust valve, and those of said air intake valve on the basis of a result of detected by said deposit volume detection section.

5. The semiconductor manufacturing system according to claim 1, wherein a plurality of said second exhaust sections are provided.

6. The semiconductor manufacturing system according to claim 1, further comprising:
a pressure sensor for sensing an internal pressure of said second exhaust section.

7. The semiconductor manufacturing system according to claim 1, wherein said air intake section draws an inert gas in lieu of the outside air.

8. The semiconductor manufacturing system according to claims 1, wherein said second exhaust section is formed so as to branch off from said first exhaust section connected to the reaction chamber, and further exhaust a by-product deposited on an interior wall of said first exhaust section.

9. The semiconductor manufacturing system according to claim 8, wherein said air intake section and said first exhaust section are connected to mutually-opposing positions of the reaction chamber.

10. A deposit elimination method for use with a semiconductor manufacturing system, comprising:
a first exhaust step of exhausting a reactive gas from a reaction chamber, after formation of a thin film on a substrate in the reaction chamber of the semiconductor manufacturing system; and
a second exhaust step of drawing outside air into the reaction chamber after said first exhaust step, and exhausting the outside air from the reaction chamber at the same time,
wherein said second exhaust step is performed at a higher exhaust rate than said first exhaust step.

11. The deposit elimination method according to claim 10, wherein the second exhaust step exhausts the outside air and a by-product deposited on an interior wall of the reaction chamber at the same time.

12. The deposit elimination method according to claim 11, further comprising:
a deposit volume detection step, prior to said second exhaust step, of detecting the volume of the by-product deposited on the interior wall surface of the reaction chamber,
wherein said second exhaust step is performed on the basis of a result detected in said deposit volume detection process.

13. The deposit elimination method according to claim 11, further comprising:
a supply volume detection step, prior to said second exhaust step, of detecting a supply volume of the reactive gas into the reaction chamber,
wherein said second exhaust step is performed on the basis of a result detected in said supply volume detection step.

14. The deposit elimination method according to claim 10, wherein said second exhaust step is performed through use of a plurality of exhaust pipes.

15. The deposit elimination method according to claim 10, wherein in said second exhaust step, an inert gas draws into the reaction chamber in lieu of the outside air.

16. A method of manufacturing a semiconductor device by the semiconductor manufacturing system according to claim 1.
